(19) United States
(12) Patent Application Publication
(10) Pub. No.: US 2008/0230895 A1
(43) Pub. Date: Sep. 25, 2008

(54) SEMICONDUCTOR PACKAGE AND THE METHOD FOR MANUFACTURING THE SAME

(75) Inventor: Yu Wen CHEN, Kaohsiung City (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING, INC., KAOHSIUNG (TW)

(21) Appl. No.: 11/870,650

(22) Filed: Oct. 11, 2007

(30) Foreign Application Priority Data
Mar. 21, 2007 (TW) 096109643

(51) Int. Cl. H01L 23/34; H01L 21/58

(52) U.S. Cl. 257/717; 438/122; 257/E23.08; 257/E21.5

(57) ABSTRACT

A method for manufacturing semiconductor packages is provided. The upper surface of a substrate has a plurality of slots and surface mount devices are positioned across the slots. In this circumstance, the space below the surface mount devices can be filled up with sealant as a result of the arrangement of the slots. This can avoid the occurrence of the melted solders to bridge to each other and of the tomb stone effect of the surface mount devices.

### CROSS REFERENCE TO RELATED APPLICATION

This application claims the priority benefit of Taiwan Patent Application Serial Number 096109643 filed Mar. 21, 2007, the full disclosure of which is incorporated herein by reference.

### BACKGROUND OF THE INVENTION

1. Field of the Invention

The invention relates to a semiconductor package and the method for manufacturing the same, and more particularly, to a semiconductor package with surface mount devices and the method for manufacturing the same.

2. Description of the Related Art

In general, a semiconductor package includes a substrate and electronic devices mounted on the substrate. Referring to FIG. 1, a conventional semiconductor package 100 includes a substrate 110 and a chip 120 attached to the upper surface 112 of the substrate 110. A plurality of surface mount devices 130, such as capacitors is mounted on bonding pads 140 on the upper surface 112 of the substrate 110 so as to electrically connect to the substrate 110.

Generally, the most common method to mount the surface mount devices 130 on the substrate 110 is by reflow process to solder both ends of the devices 130 to their corresponding bonding pads 140 with solder 160. Prior to performing the reflow process, a solder mask (not shown in the figure) has often been applied to the upper surface 112 of the substrate 110 to prevent the solder from causing a short circuit to the circuitry on the substrate 110 during the subsequent reflow process. In addition, as known in the art, it is necessary for the bonding pads 140 not to be covered with the solder mask so that the surface mount devices 130 can be soldered to the bonding pads 140.

Referring to FIG. 2, to protect the elements on the substrate 110 from damage, a sealant 150 is typically used to cover the chip 120 and devices 130. However, the devices 130 are not closely attached to the substrate 110 when they are soldered to the bonding pads 140. A gap 132 is always present between the devices 130 and substrate 110. The gap 132 is usually quite small and the molten sealant 150 therefore can hardly flow into the gap 132 during the process of forming sealant. When the substrate 110 is then subject to a heating process, for instance, mounting metal balls to the lower surface 114 of the substrate 110 to form output terminals for the semiconductor package 100, the solders 160 attaching the devices 130 to the bonding pads 140 may melt again. In the meantime, there will be a good possibility for the solders 160 to flow into the gap 132 to bridge to each other. On the other hand, the so-called “tombstone effect” may also occur where one end of the device 130 is lifted from its bonding pad 140. The foregoing adverse effects can lead to the malfunction or reduction in reliability of the package 100.

Accordingly, there exists a need to provide a method for manufacturing semiconductor packages to solve the above-mentioned problems.

### SUMMARY OF THE INVENTION

It is an object of the present invention to provide a method for manufacturing a semiconductor package that the prior art problems of solder bridging to each other and of tombstone effect can be overcome.

In one embodiment, the method for manufacturing a semiconductor package is to form at least one slot on the upper surface of a substrate. At least one surface mount device is positioned across the slot and solder is applied to both ends of the surface mount device to solder the device to the upper surface of the substrate. A ring is disposed on the upper surface of the substrate and encloses the chip and surface mount device. Afterward, a sealant is poured to the space enclosed by the ring to cover the chip and surface mount device.

According to the method of the present invention, the sealant can fill up the slot and the space below the device during the process of forming sealant because the space below the device is large enough for the sealant to flow thereto. Consequently, if the solders melt again due to subjection to a heating process, there is no possibility for the solder to free flow because the space around the solder has been occupied by the sealant. Accordingly, the above-mentioned prior art problems can be overcome. Furthermore, the ring can act as a dam to confine the flow of the sealant to the space and the sealant can therefore easily cover the chip and surface mount device.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a cross-sectional view of a conventional semiconductor package without a sealant to encapsulate the elements on the substrate.

FIG. 2 is a cross-sectional view of the semiconductor package of FIG. 1 with a sealant to cover the surface mount devices on the substrate.

FIGS. 3a and 3f illustrate the method for manufacturing a semiconductor package according to the present invention, wherein FIG. 3c is a top view and FIG. 3f illustrate a semiconductor package of the present invention.

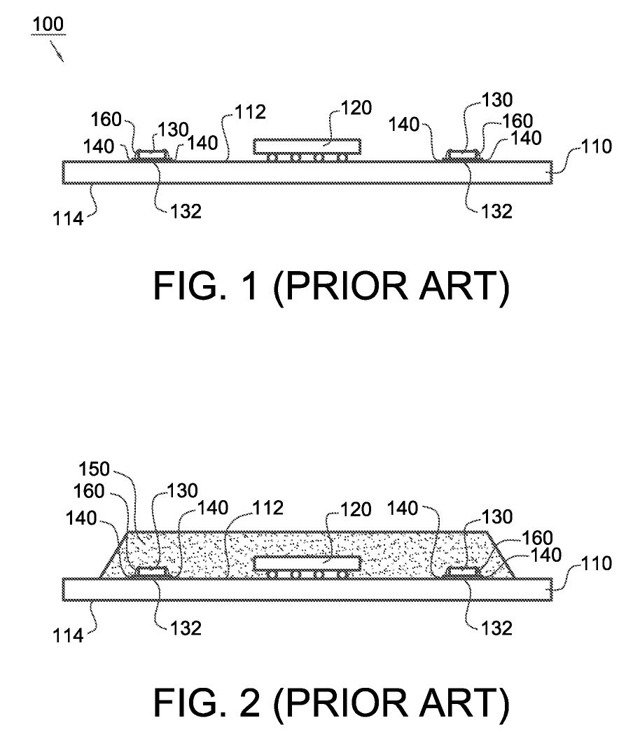

### DETAILED DESCRIPTION OF THE PREFERRED EMBODIMENT

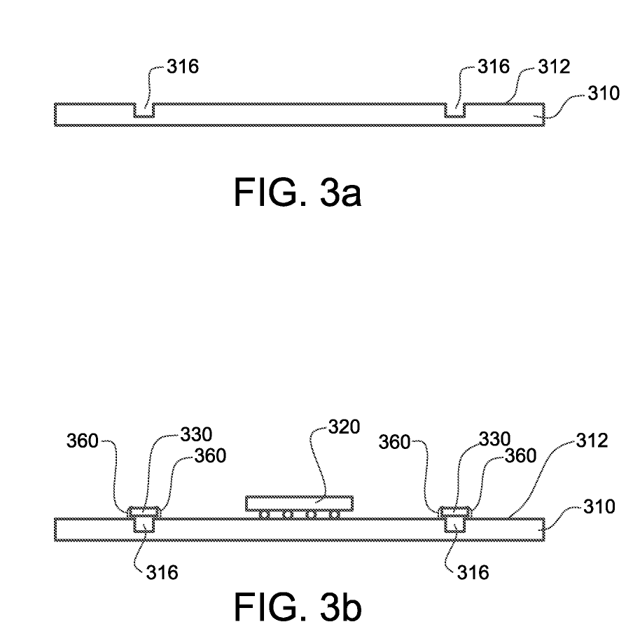

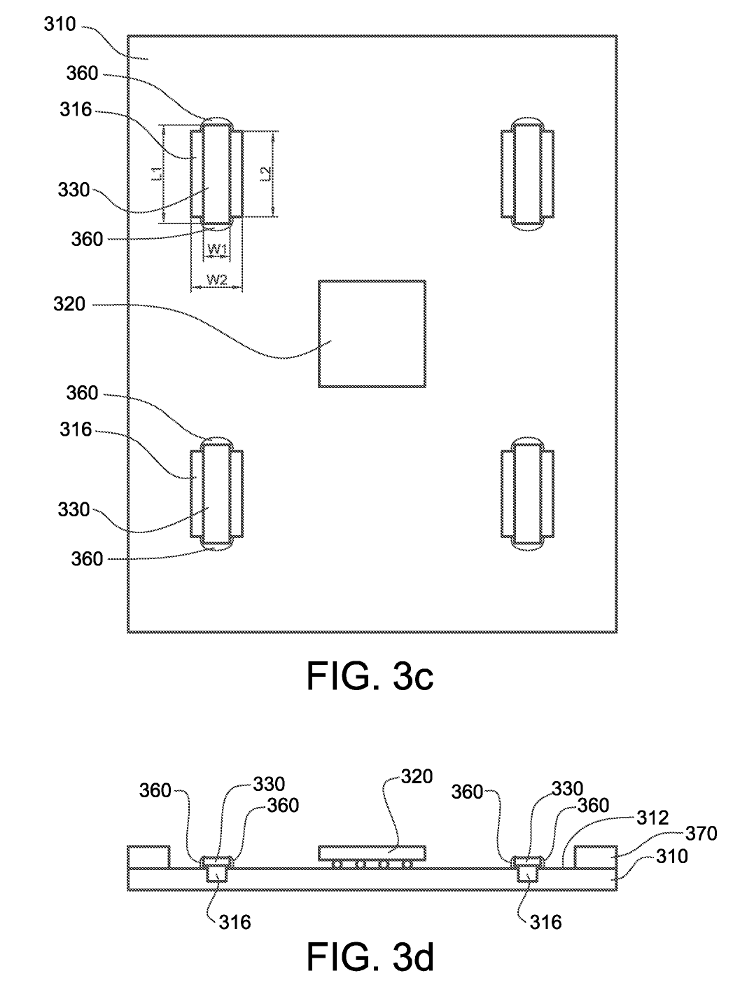

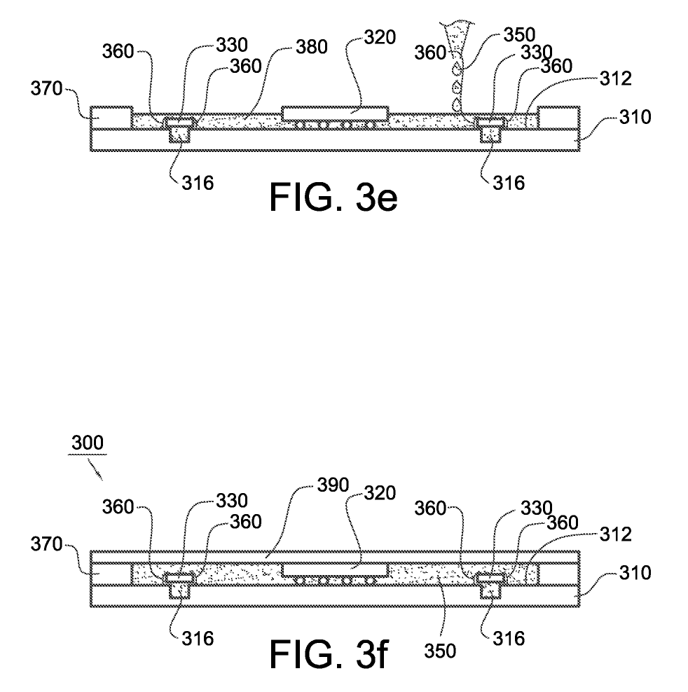

Referring to FIG. 3a, the method for manufacturing semiconductor packages according to the present invention is to form at least one slot 316 on the upper surface 312 of a substrate 310. Referring to FIG. 3b, a chip 320 is disposed on the upper surface 312 of the substrate 310. At least one surface mount device 330, such as capacitor is positioned across the slot 316 and the solder 360 is applied to both ends of the device 330 to solder the device 330 to the upper surface 312 of the substrate 310. The slot 316 can be formed by mechanical drilling or laser drilling and is sized to allow the device 330 to be positioned across the slot 316 and not to fall therein. Referring to FIG. 3c, the device 330 has a first length L1 and a first width W1. The two opposing ends of the device 330 along the first length L1 are provided with output terminals (not shown in the figure). The slot 316 has a second length L2 smaller than the first length L1 and a second width W2 larger than the first width W1. The sides of the device 330 along the first length L1 are parallel to the sides of the slot 316 along the second length L2 and the sides of the device 330 along the first width W1 are parallel to the sides of the slot 316 along the second width W2. In this circumstance, the device 330 can be positioned across the slot 316 and electrically connected to the substrate 310 by its output terminals without the fear of falling in the slot 316. Referring to 3d, a metal ring 370, such as copper ring is disposed on the upper surface 312 of the substrate 310 and encloses the chip 320 and device 330. Referring to FIG. 3e, a sealant 350 such as a liquid sealant is poured to the space 380 enclosed by the ring 370 to cover the device 330 and a least a portion of the chip 320. After the sealant 350 is hardened, its top surface is substantially flush with the top surface of the chip 320. Afterward, a heat sink 390 is disposed on the ring 370 and the chip 320 to enhance the heat dissipation of the chip 320. FIG. 3f illustrates a semiconductor package 300 of the present invention.

According to the method of the present invention, the sealant 350 can fill up the slot 316 and the space below the device 330 during the process of forming sealant as illustrated in FIG. 3e because the space below the device 330 is large enough for the sealant 350 to flow thereto. Consequently, if the solder 360 melts again due to subjection to a heating process, there is no possibility for the solder 360 to free flow because the space around the solder 360 has been occupied by the sealant 350. Accordingly, the prior art problems, i.e. solder bridging to each other and tombstone effect can be overcome. Furthermore, the ring 370 can act as a dam to confine the flow of the sealant 350 to the space 380 and the sealant 350 can therefore easily cover the chip 320 and device 330.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing a semiconductor package, comprising the steps of:
providing a substrate having an upper surface;
forming at least one slot on the upper surface of the substrate;
disposing a chip on the upper surface of the substrate;
disposing at least one surface mount device across the slot and soldering both ends of the surface mount device to the upper surface of the substrate by solder; and
pouring a sealant to the upper surface of the substrate to fill the slot and cover the surface mount device.

2. The method as claimed in claim 1, further comprising:
disposing a ring on the upper surface of the substrate to enclose the chip and the surface mount device before the sealant is poured to the upper surface of the substrate.

3. The method as claimed in claim 2, further comprising:
disposing a heat sink on the chip and the ring.

4. The method as claimed in claim 1, wherein the surface mount device is a capacitor.

5. The method as claimed in claim 2, wherein the ring is made of metal.

6. The method as claimed in claim 5, wherein the ring is made of copper.

7. The method as claimed in claim 2, wherein the surface mount device has a first length and a first width, the two opposing ends of the surface mount device along the first length are provided with output terminals, the slot has a second length smaller than the first length and a second width larger than the first width.

8. The method as claimed in claim 7, wherein the side of the surface mount device along the first length is parallel to the side of the slot along the second length, and wherein the side of the device along the first width is parallel to the side of the slot along the second width.

9. The method as claimed in claim 1, wherein the slot is formed by mechanical drilling.

10. The method as claimed in claim 1, wherein the slot is formed by laser drilling.

11. The method as claimed in claim 1, wherein the top surface of the sealant is substantially flush with the top surface of the chip after the sealant is hardened.

12. A semiconductor package, comprising:
a substrate having an upper surface and a slot formed on the upper surface;
a chip disposing on the upper surface of the substrate;
at least one surface mount device disposed across the slot and both ends of the surface mount device are soldered to the upper surface of the substrate by solder; and
a sealant formed on the upper surface of the substrate, the sealant filling up the slot and covering the surface mount device.

13. The semiconductor package as claimed in claim 12, further comprising:
a ring disposed on the upper surface of the substrate and enclosing the chip and the surface mount device.

14. The semiconductor package as claimed in claim 13, further comprising:
a heat sink disposed on the chip and the ring.

15. The semiconductor package as claimed in claim 12, wherein the surface mount device is a capacitor.

16. The semiconductor package as claimed in claim 13, wherein the ring is made of metal.

17. The semiconductor package as claimed in claim 16, wherein the ring is made of copper.

18. The semiconductor package as claim in claim 12, wherein the surface mount device has a first length and a first width, the two opposing ends of the surface mount device along the first length are provided with output terminals, the slot has a second length smaller than the first length and a second width larger than the first width.

19. The semiconductor package as claimed in claim 18, wherein the side of the device along the first length is parallel to the side of the slot along the second length, and wherein the side of the device along the first width is parallel to the side of the slot along the second width.

20. The semiconductor package as claimed in claim 12, wherein the top surface of the sealant is substantially flush with the top surface of the chip.
